(19) United States
(12) Patent Application Publication
(10) Pub. No.: US 2008/0130935 A1
(43) Pub. Date: Jun. 5, 2008

(54) Microphone package

(75) Inventors: Akiyoshi Sato, Hamamatsu-shi (JP); Shingo Sakakibara, Hamamatsu-shi (JP); Junya Suzuki, Iwata-shi (JP)

Correspondence Address: PILLSBURY WINTHROP SHAW PITTMAN LLP, P.O BOX 10500, McLean, VA, 22102, US

(73) Assignee: Yamaha Corporation, Hamamatsu-shi (JP)

(21) Appl. No.: 11/903,974

(22) Filed: Sep. 25, 2007

(30) Foreign Application Priority Data
Sep. 27, 2006 (JP) 2006-262039
Jun. 21, 2007 (JP) 2007-163952

(51) Int. Cl. H04R 11/04; H01L 21/00

(52) U.S. Cl. 381/361; 438/51; 257/E21.001

(57) ABSTRACT

A microphone package includes a housing having a cavity and a sound hole allowing the cavity to communicate with the exterior. A microphone chip is mounted on the mounting surface inside of the cavity. The sound hole is opened on the interior surface of the housing positioned opposite to the mounting surface. A resin sealing portion is formed to seal the surrounding area of the microphone chip and the mounting surface. Alternatively, a semiconductor sensor chip and a control circuit chip are mounted on the mounting surface inside of the cavity of the housing and are electrically connected together via bonding wires. Herein, the resin sealing portion entirely seals the control circuit chip and the first joining portions joining the first ends of the bonding wires, while a resin potting portion seals the second joining portions between the electrode pads and the second ends of the bonding wires.

### BACKGROUND OF THE INVENTION

1. Field of the Invention

The present invention generally relates to microphone packages encapsulating silicon condenser microphones. The present invention also relates to semiconductor devices incorporating pressure sensor chips such as sound pressure sensor chips as well as manufacturing methods of semiconductor devices.

This application claims priority on Japanese Patent Application No. 2006-262039 and Japanese Patent Application No. 2007-163952, the contents of which are incorporated herein by reference.

2. Description of the Related Art

Japanese Patent Application Publication No. 2004-537182 teaches a microphone package encapsulating a miniature silicon condenser microphone, in which a microphone chip (for detecting sound) and a LSI chip (for controlling the microphone chip) are mounted on the mounting surface of a housing having a hollow cavity. The housing has a sound hole allowing the cavity to communicate with the exterior thereof.

In this type of microphone package, when dust enters into the cavity of the housing via the sound hole or when light is unexpectedly introduced into the housing so as to reach the microphone chip, erroneous operation may occur in the silicon condenser microphone, or microphone characteristics are varied. To cope with such a disadvantage, it is preferable to reduce the size of the sound hole of the housing.

Generally speaking, Helmholtz resonation occurs in the periphery of the sound hole of the housing having the hollow cavity. As the size of the sound hole is reduced, the resonance frequency of the housing (which is determined based on the Helmholtz resonation) may be likely decreased into the audio frequency range. This degrades the quality of sound detection realized by the microphone chip.

In conventionally-known semiconductor devices (serving as silicon condenser microphones and pressure sensors), semiconductor sensor chips having transducers (such as pressure sensor chips, sound pressure sensor chips, and sound detectors for detecting sounds based on pressure variations due to vibrations) and amplifiers (or control circuit chips for driving and controlling semiconductor sensor chips) are mounted on the surfaces of substrates. In this type of semiconductor device as disclosed in Japanese Patent Application Publication No. 2004-537182, a cover is attached onto the surface of a substrate so as to form a hollow cavity for incorporating a semiconductor sensor chip and an amplifier, wherein the hollow cavity communicates with the external space of the semiconductor device via a sound hole of the cover.

This type of semiconductor device is designed such that the semiconductor sensor chip is electrically connected to the amplifier via wires, whereas the joining portions at which the wires join the semiconductor sensor chip and the amplifier may likely corrode due to environmental factors such as dust and liquid-drop unexpectedly entering into the cavity from the sound hole of the cover. This degrades the electrical reliability of the semiconductor device.

It may be possible to prevent the joining portions between the amplifier and the wires from corroding by entirely sealing the amplifier with a resin; however, it is very difficult to entirely seal the semiconductor sensor chip having the transducer. Conventional technology makes it possible to prevent the joining portions from corroding by way of gold plating performed on the semiconductor sensor chip and the wires. However, the gold plating increases the total number of steps of manufacturing, which in turn degrades the yield in manufacturing. In addition, metal plating is costly compared with resin sealing.

### SUMMARY OF THE INVENTION

It is an object of the present invention to provide a microphone package that is improved in the quality of sound detection performed by a microphone chip even when the size of a sound hole of a housing is reduced.

It is another object of the present invention to provide a semiconductor device, which can be manufactured with a relatively high yield and which is improved in electrical reliability.

In a first aspect of the present invention, a microphone package includes a housing having a cavity and a sound hole allowing the cavity to communicate with the exterior thereof, in which a microphone chip is mounted on the mounting surface inside of the cavity and in which the sound hole is opened on the interior surface of the housing positioned opposite to the mounting surface, and a resin sealing portion that is formed inside of the cavity so as to seal the surrounding area of the microphone chip and the mounting surface. Herein, the volume of the resin sealing portion is smaller than the volume of the cavity but is larger than a half of a prescribed volume, which is calculated by subtracting the volume of the microphone chip from the volume of the cavity.

Due to the formation of the resin sealing portion inside of the cavity of the housing, it is possible to reduce the volume of an effective cavity that effectively works within the cavity of the housing. Since the resonance frequency of the housing increases as the volume of the effective cavity decreases, it is possible to easily increase the resonance frequency to be higher than the audio frequency range by simply adjusting the volume of the resin sealing portion. In particular, it is possible to reliably increase the resonance frequency to be higher than the audio frequency range under the condition where the volume of the resin sealing portion is larger than a half of a prescribed volume, which is calculated by subtracting the volume of the microphone chip from the volume of the cavity. As the volume of the resin sealing portion is smaller than the prescribed volume that is calculated by subtracting the volume of the microphone chip from the volume of the cavity, it is possible for the sound transmitted from the exterior to easily reach the microphone chip via the effective cavity.

In the above, the resin sealing portion is composed of a silicon resin having a low elastic modulus and a low stress; and the microphone chip includes a diaphragm, which covers an inner hole of a support and which is arranged opposite to the mounting surface via the support. Hence, the resin sealing portion is easy to be elastically deformed during the expansion and contraction thereof due to the difference between the thermal expansion coefficient of the resin sealing portion and the thermal expansion coefficient of the housing, wherein it is possible to prevent the diaphragm from being unexpectedly deformed due to the expansion and contraction of the resin sealing portion being transmitted to the microphone chip.

As described above, it is possible to realize the following effects and technical features.
(a) By simply adjusting the volume of the resin sealing portion occupying a prescribed part of the cavity of the housing, it is possible to reliably increase the resonance frequency to be higher than the audio frequency range, wherein it is possible to improve the quality of sound detection realized by the microphone package even when the sound hole is reduced in size.
(b) It is possible to reliably increase the resonance frequency of the housing to be higher than the audio frequency range.
(c) Since the resin sealing portion is composed of a silicon resin that is easy to be elastically deformed, it is possible to prevent the diaphragm from being unexpectedly deformed due to the expansion and contraction of the resin sealing portion (which occur due to the difference between the thermal expansion coefficient of the resin sealing portion and the thermal expansion coefficient of the housing) being transmitted to the microphone chip; hence, it is possible to prevent the microphone characteristics from being unexpectedly varied.

In a second aspect of the present invention, a semiconductor device includes a housing having a cavity and a sound hole allowing the cavity to communicate with the exterior, a semiconductor sensor chip having a sound detector, which is mounted on the mounting surface inside of the cavity of the housing so as to detect pressure variations by way of vibration thereof, a control circuit chip that is mounted on the mounting surface inside of the cavity so as to drive and control the semiconductor sensor chip, a plurality of bonding wires for electrically connecting the semiconductor sensor chip and the control circuit chip together, and a resin sealing portion for entirely sealing the control circuit chip so as to embrace the first joining portions between the control circuit chip and the first ends of the bonding wires. In the above, the sound detector is exposed onto the upper surface of the semiconductor sensor chip; a plurality of electrode pads are formed in the surrounding area of the sound detector so as to join the second ends of the bonding wires; and the second joining portions between the electrode pads and the second ends of the bonding wires are sealed with a resin potting portion that is formed using the same resin material of the resin sealing portion.

A manufacturing method adapted to the semiconductor device includes a mounting step for mounting the semiconductor sensor chip and the control circuit chip onto the surface of a substrate, a wiring step for electrically connecting the control circuit chip to the electrode pads, which are formed on the upper surface of the semiconductor sensor chip for exposing the sound detector, via the bonding wires, a sealing step for forming the resin sealing portion for entirely sealing the control circuit chip so as to seal the first joining portions between the control circuit chip and first ends of the bonding wires, and the resin potting portion for sealing the second joining portions between the electrode pads and the second ends of the bonding wires, and a cover installation step for arranging the top portion so as to cover the upper side of the semiconductor sensor chip and the upper side of the control circuit chip above the mounting surface of the substrate, thus forming the housing having the cavity together with the substrate, wherein, in the sealing step, both of the resin sealing portion and the resin potting portion are formed using the same resin material.

As described above, it is possible to realize the following effects and technical features.
(a) Since the first and second joining portions are sealed with the resin sealing portion and the resin potting portion, it is possible to reliably prevent the first and second joining portions from corroding due to environmental factors such as dust and liquid drops, which may unexpectedly enter into the cavity from the sound hole. This improves the reliability regarding electrical characteristics of the semiconductor device.
(b) Since both of the resin sealing portion and the resin potting portion are formed using the same resin material, they can be collectively formed in the sealing step. This reduces the total number of manufacturing steps and controls a reduction of the manufacturing yield. The resin material is costly compared with metal plating, which may be conventionally adopted.
(c) It is preferable that a recess be formed between the sound detector and the electrode pads and be recessed from the upper surface of the semiconductor sensor chip to a prescribed position lower than an upper end of the sound detector. Even when the resin material used for the formation of the resin potting portion flows from the electrode pads to the sound detector during the sealing of the second joining portions, the resin material flows into the recess, which is recessed to be lower than the sound detector, and does not reach the sound detector.
(d) It is preferable that a dam projecting upwardly from the upper surface of the semiconductor sensor chip be formed between the electrode pads and the sound detector. Even when the resin material used for the formation of the resin potting portion flows from the electrode pads to the sound detector during the sealing of the second joining portions, the resin material is blocked by the dam and does not reach the sound detector.
(e) It is preferable that the dam be formed to surround the electrode pads. This makes it possible to prevent the resin material used for the formation of the resin potting portion from spreading in the surrounding area of the electrode pads during the sealing of the second joining portions, whereby the resin potting portion is formed only in the inside of the dam. Thus, it is possible to easily and reliably seal the second joining portions between the electrode pads and the second ends of the bonding wires.
(f) It is preferable that the housing be constituted of the substrate for mounting the semiconductor sensor chip on the mounting surface positioned opposite to the sound detector, the resin sealing portion for sealing the surrounding area of the semiconductor sensor chip and the mounting surface of the substrate, the dam that projects upwardly above the semiconductor sensor chip so as to surround the periphery of the sound detector, and the top portion that has the sound hole running through in the thickness direction and that is fixed to the distal end of the dam so as to cover the upper side of the semiconductor sensor chip, wherein the cavity is formed by way of the resin sealing portion, the dam, and the top portion.
(g) Since the resin sealing portion of the housing is closely attached to the surrounding area of the semiconductor sensor chip, it is unnecessary to form a clearance between the surrounding area of the semiconductor sensor chip and the housing; hence, it is possible to reduce the overall surface area of the substrate. By reducing the projection height of the dam, it is possible to reduce the thickness of the semiconductor device.
(h) By adjusting the projection height of the dam, which projects upwardly above the semiconductor sensor chip, it is possible to easily adjust the gap between the semiconductor sensor chip and the top portion, which are positioned opposite to each other, with a high precision. This makes it possible to prevent pressure variations, which are transmitted into the cavity via the sound hole from the exterior, from being excessively damped; hence, it is possible to improve the sensitivity of the semiconductor device with ease.
(i) In short, it is possible to prevent the manufacturing yield of the semiconductor device from being reduced so much; and it is possible to improve the reliability regarding electrical characteristics of the semiconductor device with an inexpensive constitution.

### BRIEF DESCRIPTION OF THE DRAWINGS

These and other objects, aspects, and embodiments of the present invention will be described in more detail with reference to the following drawings, in which:

FIG. 1 is a cross-sectional view showing the constitution of a microphone package, in which a microphone chip is arranged inside of a cavity of a housing, in accordance with a first embodiment of the present invention;

FIG. 2 is a longitudinal sectional view showing the constitution of a semiconductor device in accordance with a second embodiment of the present invention;

FIG. 3 is a plan view of the semiconductor device of FIG. 2;

FIG. 4 is an enlarged sectional view showing essential parts of the semiconductor device;

FIG. 5 is a longitudinal sectional view used for explaining a frame formation step and a wiring step of a manufacturing method of the semiconductor device in accordance with the second embodiment of the present invention;

FIG. 6 is a longitudinal sectional view used for explaining a sealing step of the manufacturing method of the semiconductor device in accordance with the second embodiment of the present invention;

FIG. 7 is a longitudinal sectional view used for explaining a cover installation step of the manufacturing method of the semiconductor device in accordance with the second embodiment of the present invention;

FIG. 8 is a longitudinal sectional view used for explaining the cover installation step of the manufacturing method of the semiconductor device in accordance with the second embodiment of the present invention;

FIG. 9 is a longitudinal sectional view used for explaining a mold step of the manufacturing method of the semiconductor device in accordance with the second embodiment of the present invention;

FIG. 10 is a longitudinal sectional view showing the constitution of a semiconductor device according to a first variation of the second embodiment;

FIG. 11 is a plan view showing that a dam having a linear shape is formed between a sound detector and electrode pads in the semiconductor device of FIG. 10;

FIG. 12 is a plan view showing that a dam having a U-shape is formed between the sound detector and the electrode pads in the semiconductor device of FIG. 10;

FIG. 13 is a plan view showing that the electrodes are surrounded by a dam in proximity to the sound detector in the semiconductor device of FIG. 10;

FIG. 14 is a longitudinal sectional view showing the constitution of a semiconductor device according to a second variation of the second embodiment;

FIG. 15 is a plan view showing the constitution of a semiconductor device according to a third variation of the second embodiment;

FIG. 16 is a longitudinal sectional view taken along line A-A in FIG. 15; and

FIG. 17 is a cross-sectional view taken along line B-B in FIG. 15; and

FIG. 18 is a longitudinal sectional view showing the constitution of a semiconductor device according to a fourth variation of the second embodiment.

### DESCRIPTION OF THE PREFERRED EMBODIMENTS

The present invention will be described in further detail by way of examples with reference to the accompanying drawings.

### 1. First Embodiment

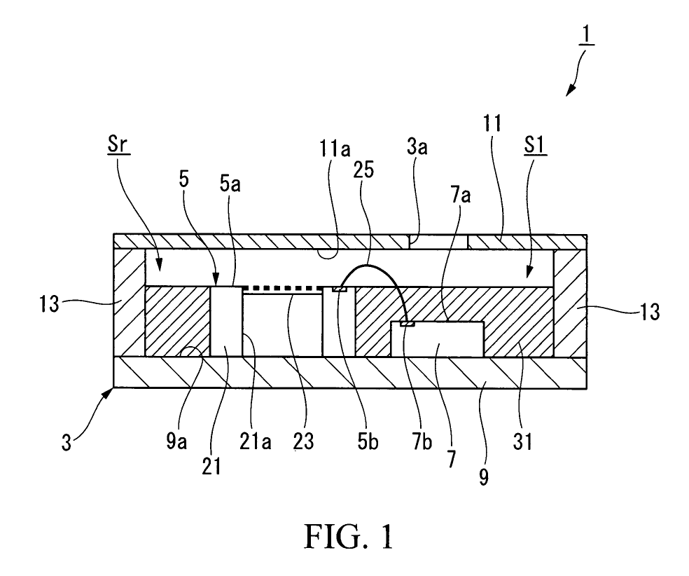

FIG. 1 shows a microphone package 1 in accordance with a first embodiment of the present invention. The microphone package 1 is constituted of a housing 3 having a cavity S1 and a sound hole 3a (allowing the cavity S1 to communicate with the exterior) as well as a microphone chip 5 and a LSI chip 7, both of which are arranged inside of the cavity S1.

The housing 3 is constituted of a substrate 9 having a mounting surface 9a, on which the microphone chip 5 and the LSI chip 7 are mounted, a top portion 11, which is distanced from the mounting surface 9a of the substrate 9 in the thickness direction, and a side wall 13, which is fixed to the circumferential periphery of an interior surface 11a of the top portion 11 positioned opposite to the mounting surface 9a of the substrate 9.

The substrate 9 is a multilayered wiring substrate in which electrical wiring (not shown) is laid, wherein the electrically wiring exposed on the mounting surface 9a is electrically connected to the LSI chip 7 via wires (not shown). The sound hole 3a runs through the top portion 11 in its thickness direction and is opened on the interior 11a of the top portion 11.

The microphone chip 5 is composed of silicon, wherein a diaphragm 23 is arranged to cover an inner hole 21a of a support 21. The diaphragm 23 detects sound by way of vibration thereof. Hence, the microphone chip 5 forms a sound pressure sensor chip for converting the vibration thereof into electric signals. The microphone chip 5 is fixed onto the mounting surface 9a of the substrate 9 via a die-bonding material (not shown) in such a way that the diaphragm 23 is positioned opposite to the mounting surface 9a of the substrate 9 via the inner hole 21a.

The LSI chip 7 drives and controls the microphone chip 5. It includes an amplifier circuit for amplifying electric signals of the microphone chip 5, for example. Similar to the microphone chip 5, the LSI chip 7 is fixed onto the mounting surface 9a of the substrate 9 via the die-bonding material (not shown).

The electrode pads 7b, which are formed on an upper surface 7a of the LSI chip 7, are electrically connected to electrode pads 5b formed on an upper surface 5a of the microphone chip 5. Due to the electrical connection between the LSI chip 7 and the substrate 9, the microphone chip 5 is electrically connected to the substrate 9 via the LSI chip 7.

The microphone package 1 is formed using a resin sealing portion 31 for sealing the mounting surface 9a of the substrate 9, the surrounding area of the support 21 of the microphone chip 5, the LSI chip 7 entirely, and a part of a wire 25 inside of the cavity S1 of the housing 3.

The resin sealing portion 31 is composed of a silicon resin having a low elastic modulus and a low stress. The resin sealing portion 31 partially fills the cavity S1 of the housing 3 at a prescribed height substantially identical to the height of the microphone chip 5 above the mounting surface 9a in such a way that it does not entirely covers the upper surface 5a of the microphone chip 5. That is, the microphone package 1 has an effective cavity Sr, which effectively works in the cavity S1 of the housing 3 and which is a space defined between the upper surface 5a of the microphone chip 5 and the upper surface of the resin sealing portion 31 as well as the interior surface 11a of the top portion 11. The sound hole 3a and the diaphragm 23 are exposed in the effective cavity Sr.

That is, the volume of the resin sealing portion 31 is smaller than the volume, which is calculated by subtracting the total volume of the microphone chip 5 and the LSI chip 7 from the volume of the cavity S1.

Next, a manufacturing method of the microphone package 1 having the aforementioned constitution will be described in detail.

In the manufacturing of the microphone package 1, the side wall 13 is fixed to the circumferential periphery of the mounting surface 9a of the substrate 9 in a side wall formation step, while the microphone chip 5 and the LSI chip 7 are mounted on the mounting surface 9a of the substrate 9 in a mounting step. Next, wire bonding is performed so as to electrically connect the microphone chip 5 and the LSI chip 7 via the wire 25, and the LSI chip 7 is electrically connected to the substrate 9 in an electrical connection step. The side wall formation step can be performed after the mounting step or after the electrical connection step.

Then, a melted resin (or a potting material) is poured onto the mounting surface 9a of the substrate 9 so as to form the resin sealing portion 31 for sealing the mounting surface 9a of the substrate 9, the surrounding area of the support 21 of the microphone chip 5, the LSI chip 7 entirely, and a part of the wire 25 in a sealing step.

The potting material used in the sealing step is composed of a silicon resin, wherein it is preferable to appropriately set the viscosity thereof. When the potting material has a very high viscosity, it is difficult for the potting material to spread entirely over the mounting surface 9a, whereas when the potting material has a very low viscosity, the potting material may likely flow onto the upper surface 5a of the microphone chip 5 via the wire 25. Specifically, an appropriate range of viscosity (or kinematic viscosity) Vp is expressed as 6.0 Pa·s<Vp<30 Pa·s. The viscosity of the potting material can be adjusted by increasing a degree of polymerization upon addition of a solvent to a silicon resin.

Lastly, the top portion 11 is fixed to the distal end of the side wall 13 in a top portion formation step. Thus, it is possible to complete the manufacturing of the microphone package 1.

Table 1 shows results of the measurement regarding resonance frequencies of the housing 3 based on the Helmholtz resonance in the microphone package 1. The measurement is performed on a sample of the microphone package 1, in which the sound hole 3a has the diameter of 0.76 mm; the top portion 11 has the thickness of 0.1 mm; the overall volume of the cavity S1 is 6.5 mm³; and the total volume of the microphone chip 5 and the LSI chip 7 is set to 2.0 mm³.

TABLE 1

| | Before formation of | After formation of resin |
|---|---|---|
| | resin sealing portion | sealing portion |
| Effective volume (mm³) | 4.5 | 3.2 |
| Volume of resin sealing | 0.0 | 1.3 |
| portion (mm³) | | |
| Resonance frequency | 16.76 | 20.01 |
| (kHz) | | |

Incidentally, the “effective volume” in Table 1 is an effectively working portion of the cavity S1 in the housing 3; that is, it is identical to the effective cavity Sr, which is realized by filling the cavity S1 with the resin sealing portion 31 as shown in FIG. 1.

The aforementioned measurement results clearly show that the resonance frequency of the housing 3 increases when the effective volume of the housing 3 is reduced by way of the formation of the resin sealing portion 31 in the cavity S1. In general, the upper-limit frequency of the audio frequency range is 20 kHz; however, as shown in Table 1, it is possible to increase the resonance frequency to be higher than the upper-limit frequency of the audio frequency range by setting the volume of the resin sealing portion 31 to 1.3 mm³. That is, when the volume of the resin sealing portion 31 becomes more than a half of the volume, which is calculated by subtracting the total volume of the microphone chip 5 and the LSI chip 7 from the volume of the cavity S1 (i.e., 4.5 mm³), it is possible to reliably increase the resonance frequency to be higher than the audio frequency range.

The aforementioned description is made with respect to the measurement results, which are produced under the condition where the upper-limit frequency of the audio frequency range is set to 20 kHz; however, the upper-limit frequency of the audio frequency range varies in accordance with the specification of a device installing the microphone package 1 therein. Therefore, it is preferable to appropriately adjust the volume of the resin sealing portion 31 in such a way that the resonance frequency of the housing 3 increases to be higher than the upper-limit frequency of the audio frequency range depending upon the specification of a device installing the microphone package 1 therein.

According to the microphone package 1 of the first embodiment, it is possible to easily reduce the effective cavity Sr, which is an effective portion of the cavity S1, by way of the formation of the resin sealing portion 31 in the cavity S1. The resonance frequency of the housing 3 increases as the effective cavity Sr decreases; hence, it is possible to easily increase the resonance frequency to be higher than the audio frequency range by adjusting the volume of the resin sealing portion 31. Therefore, even when the sound hole 3a formed in the top portion 11 of the housing 3 is reduced in size, it is possible to easily improve the quality of sound detection realized by the microphone package 1.

When the volume of the resin sealing portion 31 is larger than a half of the volume, which is calculated by subtracting the total volume of the microphone chip 5 and the LSI chip 7 from the volume of the cavity S1, it is possible to reliably increase the resonance frequency to be higher than the audio frequency range.

When the resin sealing portion 31 is composed of an “easily deformable” silicon resin, the resin sealing portion 31, which is subjected to expansion or contraction based on the difference between the thermal expansion coefficient of the housing 3 and the thermal expansion coefficient of the resin sealing portion 31, is easy to be elastically deformed. This makes it possible to prevent the diaphragm 32 from being unexpectedly deformed due to the expansion and contraction of the resin sealing portion 31 influencing the microphone chip 5. In other words, it is possible to prevent the microphone characteristics of the microphone chip 5 from being unexpectedly varied due to the expansion and contraction of the resin sealing portion 31.

In the microphone package 1 of the first embodiment, the housing 3 is mainly constituted of three constituent elements, i.e., the substrate 9, the top portion 11, and the side wall 13; but this is not a restriction. That is, the first embodiment simply requires the housing 3 to have the sound hole 3a allowing the cavity S1 to communicate with the exterior and the mounting surface 9a for mounting the microphone chip 5 and the LSI chip 7. For example, the side wall 13 can be integrally formed together with the substrate 9 so as to form the multilayered wiring substrate. Alternatively, the side wall 13 can be integrally formed together with the top portion 11 so as to form a cover member for covering the mounting surface 9a of the substrate 9.

When the top portion 11 and the side wall 13 are integrally formed together so as to form the cover member, after the completion of the mounting step and the electrical connection step, it is necessary to perform the sealing step for pouring the potting material into the cavity S1 after the cover member is fixed onto the mounting surface 9a of the substrate 9. In this sealing step, a resin material is poured into the sound hole 3a, for example.

In the first embodiment, the resin sealing portion 31 is composed of a silicon resin; but this is not a restriction. The first embodiment simply requires that the resin sealing portion 31 be formed using a resin having a low elastic modulus and a low stress in order to prevent the diaphragm 23 from being unexpectedly deformed due to the expansion and contraction of the resin sealing portion 31.

In the first embodiment, the cavity S1 is filled with the resin sealing portion 31 at a prescribed height substantially identical to the height of the microphone chip 5 above the mounting surface 9a; but this is not a restriction. The first embodiment simply requires that the resin sealing portion 31 seals the surrounding area of the support 21 of the microphone chip 5 but does not cover the upper surface 5a of the microphone chip 5.

The first embodiment is directed to the microphone package 1 incorporating the LSI chip 7; but this is not a restriction. That is, the first embodiment is applicable to any types of microphone packages each incorporating at least the microphone chip 5. In a microphone package incorporating only the microphone chip 5, when the volume of the resin sealing portion 31 becomes larger than the volume, which is calculated by subtracting the volume of the microphone chip 5 from the volume of the cavity S1, it is possible to reliably increase the resonance frequency of the housing 3 to be higher than the audio frequency range. In this case, it is necessary to reduce the volume of the resin sealing portion 31 to be smaller than the overall volume of the cavity S1 in such a way that the sound reaching the sound hole 3a from the exterior can reliably reach the microphone chip 5 and the diaphragm 23 via the effective cavity Sr.

### 2. Second Embodiment

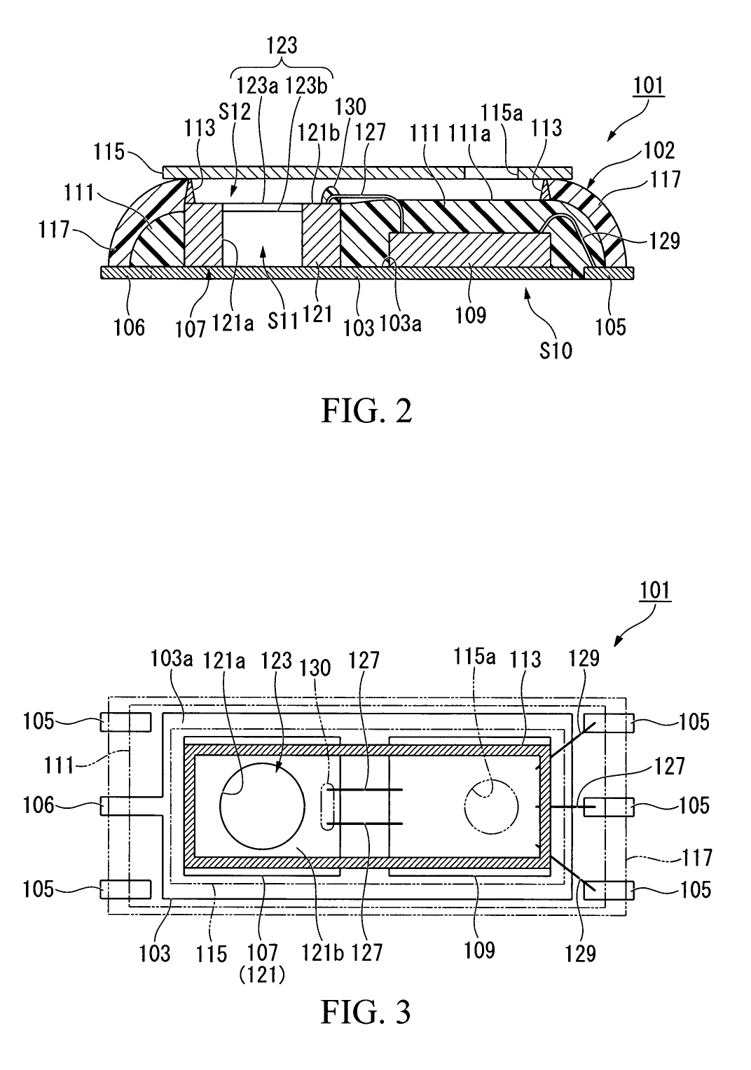

Next, a semiconductor device 101 according to a second embodiment of the present invention will be described with reference to FIGS. 2 to 9. As shown in FIGS. 2 to 4, the semiconductor device 101 is constituted of a substrate 103 composed of a metal, a plurality of metal leads 105 and 106 arranged in the periphery of the substrate 103, a semiconductor sensor chip 107 and a control circuit chip (or a LSI chip) 109, which are fixed onto a mounting surface 103a of the substrate 103, a resin sealing portion 111 formed in proximity to the mounting surface 103a of the substrate 103, a top portion (or a cover member) 115, which is fixed in position above the semiconductor sensor chip 107 and the control circuit chip 109 via a dam 113, and a resin molded portion 117 formed in the periphery of the resin sealing portion 111.

The leads 105 and 106 are each aligned along the mounting surface 103a of the substrate 103. The lead 106 is interconnected to the substrate 103, while the other leads 105 are aligned around the substrate 103 via gaps therebetween. The leads 105 and 106 and the substrate 103 are each composed of a prescribed metal material such as copper or 42-alloy (i.e., iron-nickel alloy).

The semiconductor sensor chip 107 is constituted of a support 121 having an inner hole 121a running in the thickness direction, a sound detector 123 that is arranged to cover the inner hole 121a so as to detect pressure variations by way of vibration, and a plurality of electrode pads 125 (e.g., two electrode pads 125) that are formed on an upper surface 121b of the support 121 surrounding the inner hole 121a so as to detect detection signals output from the sound detector 123. The semiconductor sensor chip 107 is a microphone chip, for example.

The support 121 is formed by laminating a monocrystal silicon substrate 122 with three protection films 122a, 122b, and 122c. It is required that each of a first protection film 122a, a second protection film 122b, and a third protection film 122c have insulating property and is thus composed of an oxide film (SiO₂), a silicon nitride film (Si₃N₄), a silicon oxide nitride film (SiON), or an alumina film (Al₂O₃), for example.

The sound detector 123 is constituted of a fixed electrode 123a, which covers the inner hole 121a of the support 121, and a diaphragm 123b, which is positioned opposite to the fixed electrode 123a with a prescribed distance therebetween in the thickness direction of the support 121 and which vibrates due to pressure variations applied thereto.

The diaphragm 123b is formed using a conductive semiconductor film having a disk-like shape, wherein the outer circumferential periphery thereof is embedded between the monocrystal silicon substrate 122 and the first protection film 122a formed just above the substrate 122 in the support 121.

The fixed electrode 123a is formed using a conductive semiconductor film having a disk-like shape, wherein the outer circumferential periphery thereof is embedded between the first protection film 122a and the second projection film 122b formed just above the first protection film 122a. A plurality of holes 123c are formed to run through the center portion of the fixed electrode 123a, which covers the inner hole 121a of the support 121, in the thickness direction.

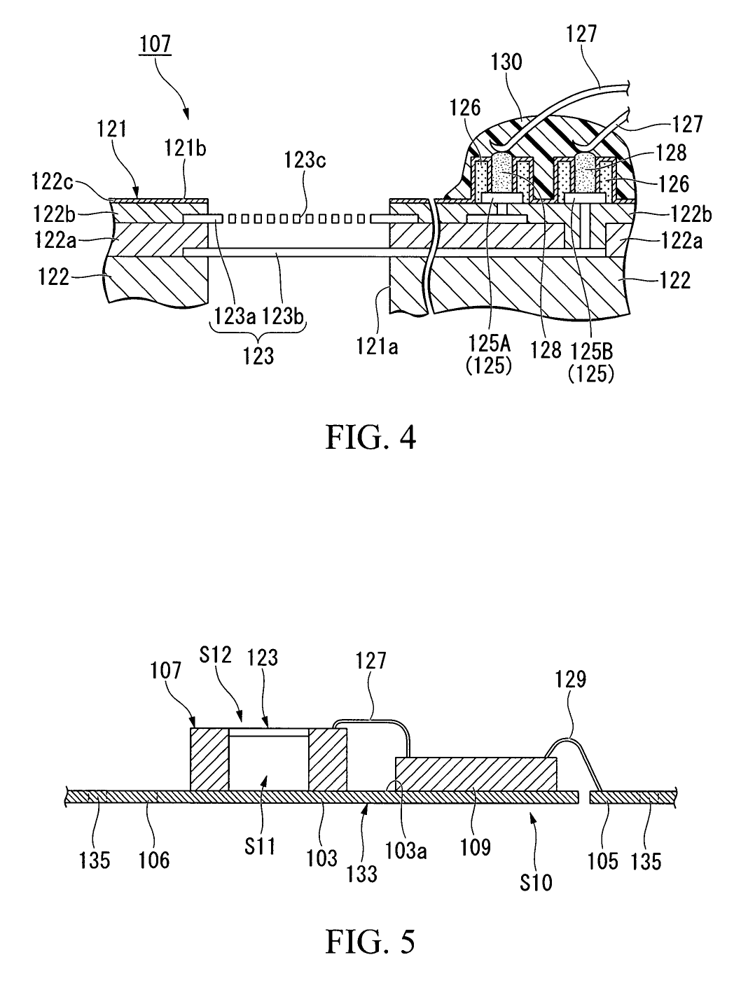

The plural electrode pads 125 are formed on the second protection film 122b, and bump holding portions 126 (composed of passivation films) project upwardly from the surrounding areas of the electrode pads 125. The bump holding portions 126 are used to hold bumps 128, which are formed on the electrode pads 125 in wiring bonding. Specifically, as shown in FIG. 4, a first electrode pad 125A is electrically connected to the fixed electrode 123a, and a second electrode pad 125B is electrically connected to the diaphragm 123b.

The semiconductor sensor chip 107 is fixed onto the surface 103a of the substrate 103 by use of the insulating adhesive having electrically insulating property or the die-bonding material such as a die-attach film in such a way that the sound detector 123 is positioned opposite to the surface 103a of the substrate 103 via the inner hole 121a of the support 121. When fixed, the semiconductor sensor chip 107 forms a back cavity (or a back air chamber) S11, which is closed in an airtight manner, together with the sound detector 123, the inner hole 121a of the support 121, and the surface 103a of the substrate 103.

The control circuit chip 109 drives and controls the semiconductor sensor chip 107, wherein it includes an amplifier circuit for amplifying electric signals output from the semiconductor sensor chip 107, an A/D converter for digitally processing electric signals, and a digital signal processor (DSP), for example. Similar to the semiconductor sensor chip 107, the control circuit chip 109 is fixed onto the surface 103a of the substrate 103 by use of the insulating adhesive and the die-bonding material (such as a film).

The control circuit chip 109 is electrically connected to the semiconductor sensor chip 107 by use of first bonding wires 127. The control circuit chip 109 is electrically connected to the prescribed leads 105, which are selected from among the aforementioned leads 105, by use of second bonding wires 129. This makes it possible for the semiconductor sensor chip 107 to be electrically connected to the prescribed leads 105 within the aforementioned leads 105. Incidentally, distal ends of the first bonding wires 127 join the electrode pads 125 respectively.

The resin sealing portion 111 seals the surface 103a of the substrate 103, the surrounding area of the semiconductor sensor chip 107, the control circuit chip 109 including the joining portions between the control circuit chip 109 and the first bonding wires 127, and the second bonding wires 129 entirely. Herein, the resin sealing portion 111 is closely attached to the side wall of the support 121 entirely but is not formed on the upper surface 121a of the support 121. Therefore, the sound detector 123 is exposed to the outside of the resin sealing portion 111 from the upper surface 121b of the support 121.

The resin sealing portion 111 also seals the leads 105 and 105 together with the surface 103a of the substrate 103; hence, it integrally fixes the leads 105 and 106 together with the substrate 103 in prescribed positioning.

A resin potting portion 130 is formed on the upper surface 121b of the semiconductor sensor chip 107 so as to seal the joining portions between the electrode pads 125 and the first bonding wires 127. The resin potting portion 130 is formed using the same material as the resin sealing portion 111. In figures, plural joining portions are sealed with a single resin potting portion 130. Alternatively, it is possible to form a plurality of resin potting portions 130 for sealing the joining portions respectively.

The dam 113 composed of a resin is formed to surround the external area of the diaphragm 123b and is elongated over the upper surface 121b of the support 121 and a surface 111a of the resin sealing portion 111, wherein it projects upwardly from the semiconductor sensor chip 107. Specifically, the dam 113 entirely surrounds the semiconductor sensor chip 107 and the control circuit chip 109 in plan view. It is preferable that the dam 113 be closely bonded to the upper surface 121b of the semiconductor sensor chip 107 and the surface 111a of the resin sealing portion 111 without any gap therebetween.

The top portion 115 is adhered and fixed onto the distal end of the dam 113, so that it is positioned above the upper surface 121b of the semiconductor sensor chip 107 and the surface 111a of the resin sealing portion 111 with a prescribed gap therebetween. In this state, the top portion 115 entirely covers the upper side of the semiconductor sensor chip 107 and the upper side of the control circuit chip 109. Incidentally, the prescribed gap depends upon the projection height of the dam 113. Since the top portion 115 is bonded onto the dam 113 without any gap therebetween, it is possible to form a hollow cavity S12 by way of the resin sealing portion 111, the dam 113, and the top portion 115.

A sound hole 115a is formed to run through the top portion 115 in its thickness direction; hence, the cavity S12 communicates with the exterior via the sound hole 115a. The sound hole 115a is formed at a prescribed position of the top portion 115, which is not opposite to the sound detector 123. This guarantees that the sound detector 123 is not directly exposed to the exterior.

The top portion 115 is composed of a conductive material. The top portion 115 is electrically connected to a ground pattern of a circuit board (not shown) for mounting the semiconductor device 101, whereby it is possible to form an electromagnetic shield for blocking electromagnetic noise from entering into the cavity S12 via the top portion 115 from the exterior.

The resin mold portion 117 is formed externally of the cavity S12, wherein it comes in contact with the leads 105 and 106, the resin sealing portion 111, the dam 113, and the top portion 115 so as to integrally fix them in prescribed positioning. In addition, the bonded portion between the top portion 115 and the semiconductor sensor chip 107 and the bonded portion between the resin sealing portion 111 and the dam 113 are embedded in the resin mold portion 117, which thus forms the external shape of the semiconductor device 101 together with the substrate 103 and the top portion 115. That is, the resin mold portion 117 reinforces the bonding strength between the dam 113, the resin sealing portion 111, and the top portion 115.

As described above, the housing 102 having the hollow cavity S12 and the sound hole 115a (allowing the cavity S12 to communicate with the exterior) is constituted of the substrate 103, the resin sealing portion 111, the dam 113, the top portion 115, and the resin mold portion 117.

Next, a manufacturing method of the semiconductor device 101 having the aforementioned constitution will be described in detail with reference to FIGS. 5 to 9.

As shown in FIG. 5, a thin metal plate composed of a metal material such as copper and 42-alloy is subjected to press working and etching so as to form a plurality of lead frames 133, each of which is constituted of the substrate 103, the leads 105 and 106, and a dam bar 135, which are integrally interconnected together in a frame formation step. Herein, the adjacent lead frames 133 are interconnected by means of the dam bar 135.

Next, the semiconductor sensor chip 107 and the control circuit chip 109 are bonded and fixed onto the surface 103a of the substrate 103 by use of the insulating adhesive or the die-bonding material such as the die-attach film having electrically insulating property in a mounting step. It is preferable to use the die-bonding material having a low elastic modulus. When a thermosetting resin is used as the die-bonding material, it is preferable that the die-bonding material be subjected to hardening conditions in which it is heated at a prescribed temperature ranging from 120° C. to 200° C. for a prescribed time ranging from 30 minutes to 1 hour, for example. It is possible to list “EN4390N” (manufactured by Hitachi Chemical Co. Ltd.) as an example of the die-bonding material. In this case, hardening is realized by heating the die-bonding material at 150° C. for 1 hour or so by use of an oven in a N₂ atmosphere or dry-air atmosphere.

After completion of the mounting step, wire bonding is performed so that the first bonding wires 127 are laid between the semiconductor sensor chip 107 and the control circuit chip 109, and the second bonding wires 129 are laid between the control circuit chip 109 and the prescribed leads 105 within the aforementioned leads 105, whereby the semiconductor sensor chip 107 is electrically connected to the prescribed leads 105 via the control circuit chip 109 in a wiring step.

When the distal ends of the first bonding wires 127 join the semiconductor sensor chip 107, the bumps 128 are formed on the electrode pads 125 of the semiconductor sensor chip 107 in advance by means of a capillary (not shown) used for the wire bonding; then, the distal ends of the first bonding wires 127 join the bumps 128 (see FIG. 4).

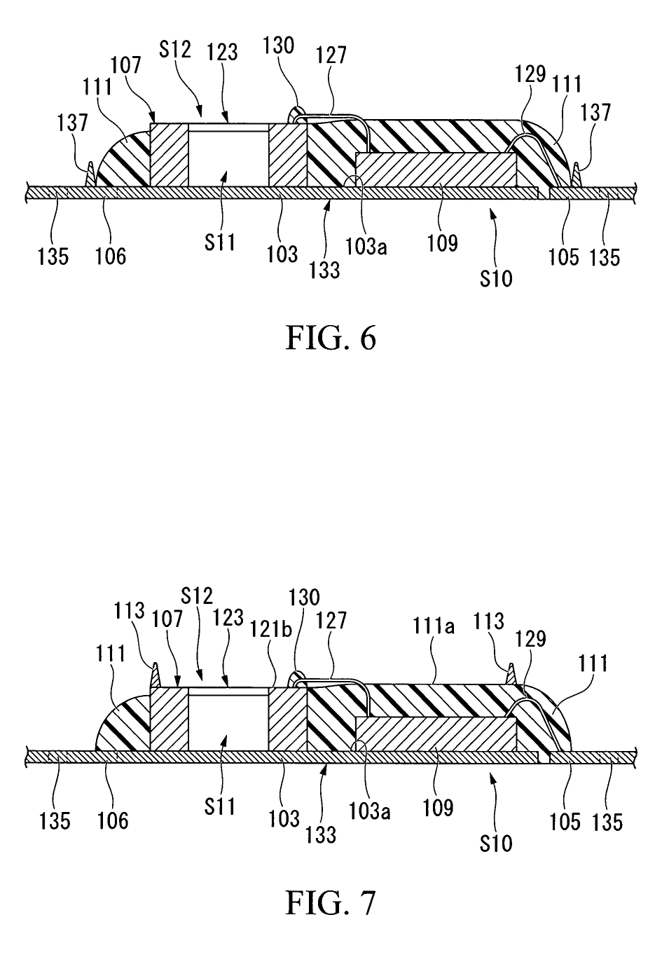

Then, as shown in FIG. 6, the resin sealing portion 111 is formed to seal the surrounding area of the semiconductor sensor chip 107, the surface 103a of the substrate 103, and the control circuit chip 109 including the joining portions between the distal ends of the first bonding wires 127 and the control circuit chip 109, while the resin potting portion 130 is formed to seal the joining portions between the electrode pads 125 of the semiconductor sensor chip 107 and the distal ends of the first bonding wires 127 in a sealing step.

In the sealing step, a rib 137 is formed on the surface 103a of the substrate 103 so as to entirely surround the substrate 103 and to partially surround the leads 105 and 106 by use of an application device such as a dispenser (not shown). Next, a resin (or a potting material) is poured into the area surrounded by the rib 137 so as to form the resin sealing portion 111. In this process, the second bonding wires 129 for connecting the control circuit chip 109 and the prescribed leads 105 are entirely sealed with the resin sealing portion 111. After completion of the formation of the resin sealing portion 111, the rib 137 is removed.

In the sealing step, as shown in FIG. 4, the same resin material (or the same potting material) of the resin sealing portion 111 is poured into the joining portions between the electrode pads 125 and the distal ends of the first bonding wires 127, thus forming the resin potting portion 130. Incidentally, the resin potting material 130 can be formed before or after the formation of the resin sealing portion 111.

As the potting material used for the formation of the resin sealing portion 111 and the resin potting portion 130, it is possible to selectively use a silicon resin or an epoxy resin, for example. When a thermosetting resin is used as the potting material, it is preferable to set the hardening conditions in which the heating temperature ranges from 100° C. to 200° C., and the heating time ranges from 30 minutes to 3 hours.

As the potting material, it is possible to list “LMC-22” (manufactured by Shin-Etsu Chemical Co. Ltd.), for example. This potting material is hardened and heated in an oven at 150° C. for 2 hours or so.

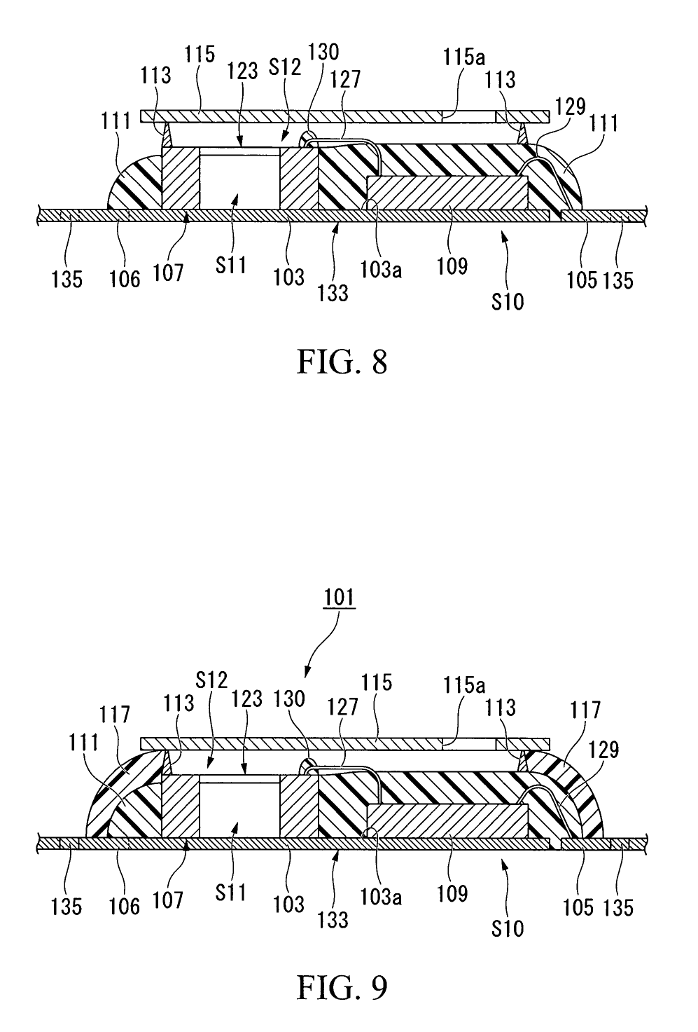

After completion of the sealing step, as shown in FIGS. 7 and 8, the top portion 115 is arranged above the surface 103a of the substrate 103 so as to cover the semiconductor sensor chip 107 and the resin sealing portion 111 by way of the dam 113 surrounding the external area of the diaphragm 123b, and then the top portion 115 is fixed onto the dam 113 in a cover installation step.

In the cover installation step, as shown in FIG. 7, the dam 113 is formed first. Similar to the rib 137, the dam 113 is formed by means of the application device such as a dispenser (not shown) in such a way that a resin is elongated over the upper surface 121b of the dam 113 and the surface 111a of the resin sealing portion 111. It is preferable that the distal end of the dam 113, which projects upwardly above the upper surface 121b of the semiconductor sensor chip 107 and the surface 111a of the resin sealing portion 111 be horizontally positioned substantially in the same plane. Preferably, the projection height of the dam 113 should be higher than the heights of the first bonding wires 127 and the height of the resin potting portion 130 so that the top portion 115 does not come in contact with the first bonding wires 127 and the resin potting portion 130.

In the cover installation step, the dam 113 is not hardened but the resin material therefor has a high viscosity not causing a collapse of the shaping of the dam 113. As the resin material used for the formation of the dam 113, it is preferable to use a thermosetting resin such as “X-43-5255” (manufactured by Shin-Etsu Chemical Co. Ltd.).

Next, as shown in FIG. 8, the top portion 115 is bonded and fixed to the distal end of the dam 113. That is, the top portion 115 is arranged on the distal end of the dam 113, and then the dam 113 is hardened so that the top portion 115 is fixed in position by way of the bonding property of the dam 13. Even when small irregularities are formed on the distal end of the dam 113, the top portion 115 is pressed onto the distal end of the dam 113 so as to partially deform the dam 113; this makes it possible for the top portion 115 to reliably join the dam 113 without any gap therebetween.

When a thermosetting material is used for the formation of the dam 113, the dam 113 can be heated and hardened after it is deformed as described above. It is preferable to set the hardening conditions for the dam 113 in which the heating temperature ranges from 120° C. to 150° C., and the heating time ranges from 30 minutes to 2 hours. When the aforementioned potting material entitled “X-43-5255” is used for the formation of the dam 113, it is heated and hardened in an oven at 150° C. for 2 hours or so. Thus, it is possible to complete the cover installation step.

Next, as shown in FIG. 9, the resin mold portion 17 is formed so as to embed the bonded portion between the top portion 115 and the semiconductor sensor chip 107 and the bonded portion between the resin sealing portion 111 and the dam 113 therein and to integrally fix the leads 105 and 106, the resin sealing portions 111, the dam 113, and the top portion 115 in prescribed positioning in a mold step. Similar to the sealing step, a rib (not shown) is formed in the surrounding area of the resin sealing portion 111; then, a resin is poured into the area surrounded by the rib so as to form the resin mold portion 117. The rib is removed after completion of the formation of the resin mold portion 117. As the resin poured into the surrounding area of the rib, it is preferable to use a resin whose viscosity ranges from 20 Pa·s to 200 Pa·s, whose hardening temperature (or heating temperature) ranges from 120° C. to 280° C., and whose heating time ranges from 60 minutes to 240 minutes.

Lastly, the dam bar 135 for interconnecting the adjacent lead frames 133 is cut out so as to isolate the individual lead frames 133, in which the substrates 103 and the leads 105 and 106 are individually divided in a cutting step. Thus, it is possible to complete the manufacturing of the semiconductor device 101.

In the semiconductor device 101 that is manufactured by way of the aforementioned manufacturing method, the joining portions between the electrode pads 125 of the control circuit chip 109 and the first bonding wires 127 are sealed with the resin sealing portion 111 and the resin potting portion 130; hence, it is possible to prevent the joining portions from corroding due to environmental factors such as dust and liquid drops, which enter into the cavity S2 via the sound hole 115a. Thus, it is possible to improve the reliability regarding electrical characteristics of the semiconductor device 101.

Since both of the resin sealing portion 111 and the resin potting portion 130 are composed of the same potting material, they can be formed by way of the same manufacturing step (i.e., the sealing step). This reduces the total number of manufacturing steps, and this suppresses a reduction of the yield in manufacturing. In addition, the aforementioned potting material is inexpensive compared with the conventional metal plating.

In short, it is possible to suppress a reduction of the yield in the manufacturing of the semiconductor device 101, and it is possible to improve the reliability regarding electrical characteristics of the semiconductor device 101 without increasing the manufacturing cost.

Since the resin sealing portion 111 is closely attached to the surrounding area of the semiconductor sensor chip 107, it becomes unnecessary to form a clearance, which is required in the conventional technology to cover the surrounding area of the semiconductor sensor chip 107.

The elimination of the clearance around the semiconductor sensor chip 107 makes it possible to reduce the area of the surface 103a of the substrate 103. This realizes the downsizing of the semiconductor device 101; hence, it is possible to reduce the mounting area of a circuit board for mounting the semiconductor device 101. By reducing the projection height of the dam 113, it is possible to reduce the thickness of the semiconductor device 101.

By adjusting the projection height of the dam 113, which projects upwardly above the semiconductor sensor chip 107, it is possible to easily adjust the gap between the semiconductor sensor chip 107 and the top portion 115, with a high precision. This makes it possible to reduce the volume of the cavity S12. That is, it is possible to control pressure variations, which are transmitted into the cavity S12 via the sound hole 115a from the exterior, from being damped in the cavity S12; hence, it is possible to easily improve the sensitivity of the semiconductor device 101.

Due to the formation of an electromagnetic shield for blocking electromagnetic noise from entering into the cavity S12 via the top portion 115 from the exterior, it is possible to avoid erroneous operation of the semiconductor sensor chip 107 due to electromagnetic noise. When the gap between the semiconductor sensor chip 107 and the top portion 115 and the gap between the control circuit chip 109 and the top portion 115 are reduced by adjusting the projection height of the dam 113, it is possible to further improve an electromagnetic shield effect.

The projection height of the dam 113 can be controlled by controlling a resin material (forming the dam 113) discharged from the application device such as a dispenser. Alternatively, it is possible to use a mount mechanism for controlling the position of the top portion 115, wherein the top portion 115 is pressed onto the dam 113 before being hardened so as to control an amount of deformation of the dam 113.

The leads 105 and 106, the resin sealing portion 111, the dam 113, and the top portion 115 are integrally fixed in prescribed positioning by means of the resin mold portion 117. This reinforces the adhesive strength between the resin sealing portion 111 and the dam 113 and the adhesive strength between the top portion 115 and the dam 113; hence, it is possible to hold the fixation between the dam 113 and the top portion 115.

Since the control circuit chip 109 is completely sealed with the resin sealing portion 111, it is possible to offer an outstanding effect in which the semiconductor device 101 is hardly influenced by disturbance such as noise.

According to the manufacturing method of the semiconductor device 101, a plurality of lead frames 133 including the substrates 103 are simultaneously formed on the same thin metal plate in the frame formation step. Hence, a series of steps such as the mounting step and the cover installation step can be each collectively performed on the same thin metal plate. That is, it is possible to collectively manufacture a plurality of semiconductor devices; hence, it is possible to improve the manufacturing efficiency with regard to the semiconductor device 101.

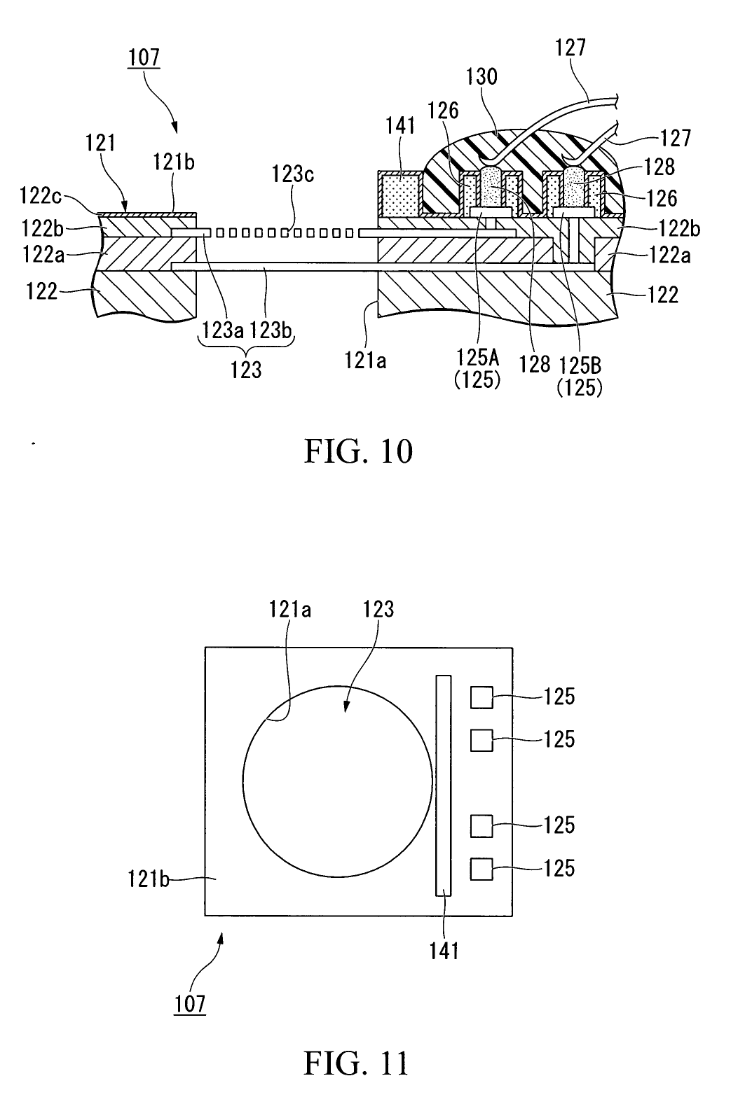

The second embodiment can be further modified in a variety of ways. FIG. 10 shows a first variation of the second embodiment, wherein a dam 141 is additionally formed to project upwardly from the upper surface 121b of the support 121 at a prescribed position between the electrode pads 125 and the fixed electrode 123a. Herein, it is necessary to form a gap between the dam 141 and the bump holding portion 126.

Similar to the bump holding portions 126, the dam 141 can be formed with the formation of the semiconductor sensor chip 107. Alternatively, similar to the dam 113 and the rib 137, the dam 141 can be formed independently of the semiconductor sensor chip 107 after the formation of the semiconductor sensor chip 107, wherein it is formed on the upper surface 121b of the semiconductor sensor chip 107. When the dam 141 is independent of the semiconductor sensor chip 107, it is necessary for the dam 141 to be formed before the formation of the resin potting portion 130.

According to the aforementioned constitution, even when the potting material having a low viscosity flows from the electrode pads 125 to the sound detector 123 in the sealing step, in which the joining portions between the electrode pads 125 and the distal ends of the first bonding wires 127 are sealed with the resin potting portion 130, the potting material is blocked by the dam 141 so that the potting material flows into the gap between the bump holding portion 126 and the dam 141; hence, it is possible to reliably prevent the potting material from reaching onto the sound detector 123.

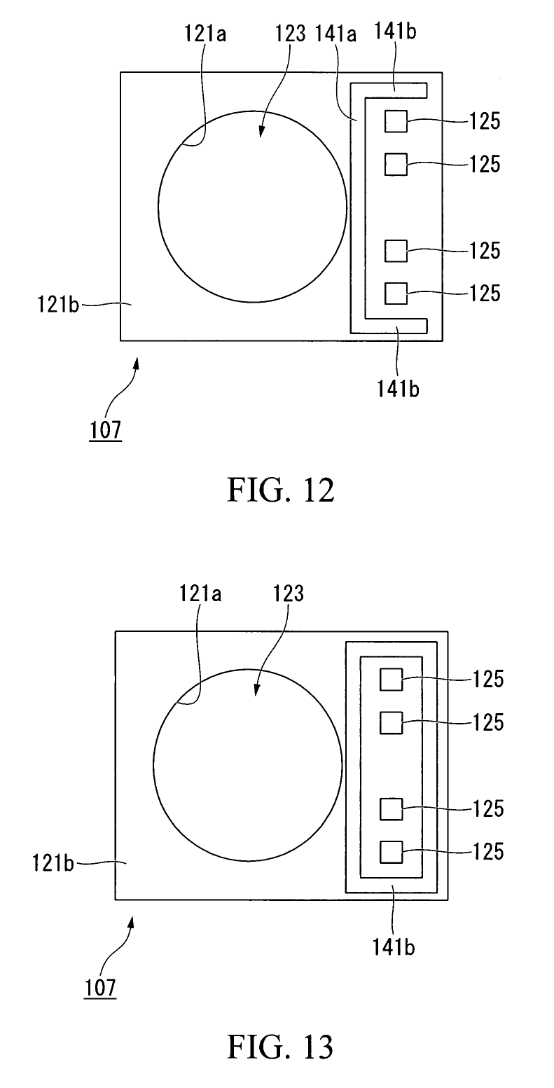

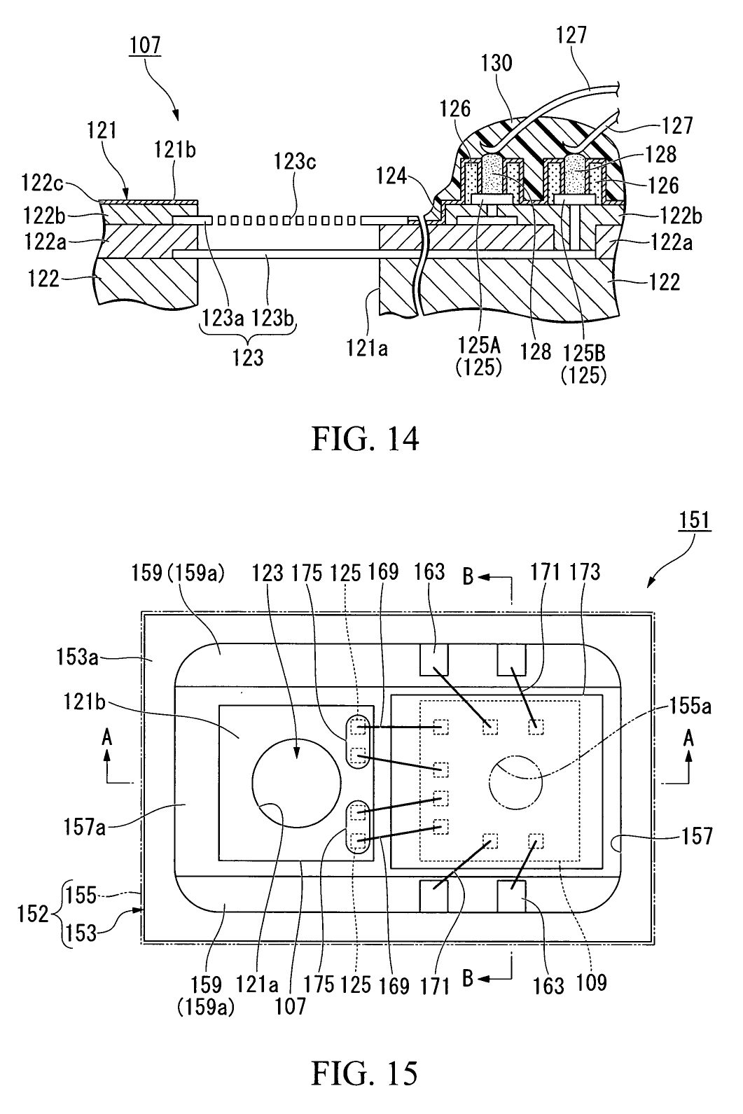

As shown in FIG. 11, the dam 141 can be formed in a linear shape in plan view between the sound detector 123 and the electrode pads 125. Alternatively, as shown in FIG. 12, the dam 141 can be formed substantially in a U-shape in plan view, wherein the dam 141 is constituted of a linear wall 141a positioned between the sound detector 123 and the electrode pads 125 and a pair of side walls 141b that are elongated from both ends of the linear wall 141a in a direction perpendicular to the alignment direction of the electrode pads 125 so as to embrace the electrode pads 125. When the dam 141 is formed substantially in the U-shape as shown in FIG. 12, it is possible to prevent the potting material from reaching onto the sound detector 123 via the side portions of the linear wall 141a during the formation of the resin potting portion 130.

The dam 141 can be formed to surround the electrode pads 125 in plan view as shown in FIG. 13. The dam 141 is not necessarily shaped to collectively surround the electrode pads 125. Alternatively, the dam 141 can be shaped to individually surround each of the electrode pads 125.

In the aforementioned constitution, it is possible to prevent the potting material used for the formation of the resin potting portion 130, which seals the joining portions between the electrode pads 125 and the distal ends of the first bonding wires 127, from spreading in the surrounding area of the electrode pads 125; hence, it is possible to reliably form the resin potting portion 130 inside of the dam 141 only. This makes it possible for the resin potting portion 130 to easily and reliably seal the aforementioned joining portions.

Instead of the dam 141, it is possible to form a recess 124 at a prescribed position between the fixed electrode 123 and the electrode pads 125, wherein the recess 124 is recessed downwardly from the upper surface 121b of the support 121 and is lower than the upper end of the sound detector 123. Specifically, the recess 124 is formed using the side portion of the fixed electrode 123a, the surface of the first protection film 122a covered with the third protection film 122c, and the side portion of the second protection film 122b, wherein it can be manufactured with the formation of the semiconductor sensor chip 107. The area of the recess 124 can be shaped identically to each of the dams 141 shown in FIGS. 11 to 13. Alternatively, the recess 124 can be formed entirely on the upper surface 121b of the support 121 except for the areas of the electrode pads 125 and the areas of the bump holding portions 126.

In the aforementioned constitution, even when the potting material used for the formation of the resin potting portion 130 flows from the electrode pads 125 to the sound detector 123 during the sealing step, the potting material flows into the recess 124, which is recessed to be lower than the upper end of the sound detector 123. That is, the recess 124 works similar to the dam 141; hence, it is possible to prevent the potting material from reaching onto the sound detector 123.

The recess 124 is not necessarily formed in the side portion of the fixed electrode 123a. It is required that the recess 124 be recessed from the upper surface 121a of the support 121 to be lower than the upper end of the sound detector 123 at a prescribed position between the sound detector 123 and the electrode pads 125. For this reason, under the condition where the outer circumferential periphery of the fixed electrode 123a is covered with the second protection film 122b, the recess 124 that is recessed from the upper surface 121a of the support 121 can be formed in the second protection film 122b positioned between the sound detector 123 and the electrode pads 125. In this case, the bottom and side wall of the recess 124 can be formed using only the second protection film 122b covered with the third protection film 122c. Alternatively, the bottom of the recess 124 is formed using the first protection film 122a covered with the third protection film 122c, and the side wall of the recess 124 is formed using the second protection film 122b covered with the third protection film 122c.

In the present embodiment, the top portion 115 is directly attached onto the distal end of the dam 113 composed of a resin; but this is not a restriction. For example, the top portion 115 can be adhered onto the distal end of the dam 113 via the adhesive. This constitution is advantageous because the top portion 115 can be fixed to the dam 113 after hardening; hence, it is possible to set the gap between the semiconductor sensor chip 107 and the top portion 115 with a high precision.

The dam 113 is not necessarily formed by way of the application of a resin. For example, the dam 113 can be formed using a sheet of an enclosure shape that is prepared in advance. The sheet has an adhesive property; alternatively, the sheet can be adhered to the semiconductor sensor chip 107, the resin sealing portion 111, and the top portion 115 via the adhesive.

In the cover installation step, after the dam 113 is formed on the upper surface 121b of the semiconductor sensor chip 107 and the surface 111a of the resin sealing portion 111, the dam 113 is attached and fixed to the top portion 115; but this is not a restriction. For example, after the dam 113 is formed in connection with the top portion 115, the dam 113 can be attached and fixed to the upper surface 121b of the semiconductor sensor chip 107 and the surface 111a of the resin sealing portion 111. In this case, when the dam 113 is directly attached and fixed to the surface 121b of the semiconductor sensor chip 107 and the surface 111a of the resin sealing portion 111, the dam 113 is arranged on the upper surface 121b of the semiconductor sensor chip 107 and the surface 111a of the resin sealing portion 111 before it is hardened; thereafter, the dam 113 is deformed so as to control the positioning thereof in relation to the top portion 115, and then the dam 113 is hardened.

In the sealing step, a resin is poured into the inside of the rib 137 surrounding a single substrate 103 so as to form the resin sealing portion 111; but this is not a restriction. For example, a rib for collectively surrounding all the substrates 103 is formed on the thin metal plate 131; then, a resin is poured into the inside of the rib so as to collectively form the plural resin sealing portions 111 for the plural semiconductor devices 101.

Similarly, in the mold step, a rib for collectively surrounding all the substrates 103 is formed in advance; then, a resin is poured into the inside of the rib so as to collectively form the plural resin mold portions 117 for the plural semiconductor devices 101.

After the plural resin sealing portions 111 and the plural resin mold portions 117 are collectively formed on the thin metal plate 131, they are divided into individual pieces in a cutting step.

The aforementioned modifications are advantageous because it is easy to form the aforementioned ribs for defining the regions of the resin sealing portions 111 and the regions of the resin mold portions 117, wherein the resins can be collectively introduced into the insides of the ribs; hence, it is possible to further improve the manufacturing efficiency of the semiconductor device 101.

Incidentally, the semiconductor device 101 is not necessarily equipped with the resin mold portion 117. Because, it is unnecessary to form the resin mold portion 117 as long as an adequate adhesion is established between the dam 113 and each of the semiconductor sensor chip 107, the resin sealing portion 111, and the top portion 115.

The present invention is not necessarily limited to the second embodiment as well as the first and second variations. That is, the present invention is applicable to any types of semiconductor devices, each of which is equipped with the semiconductor sensor chip 107 and the control circuit chip 109 in the housing having the hollow cavity and the sound hole allowing the cavity to communicate with the exterior.

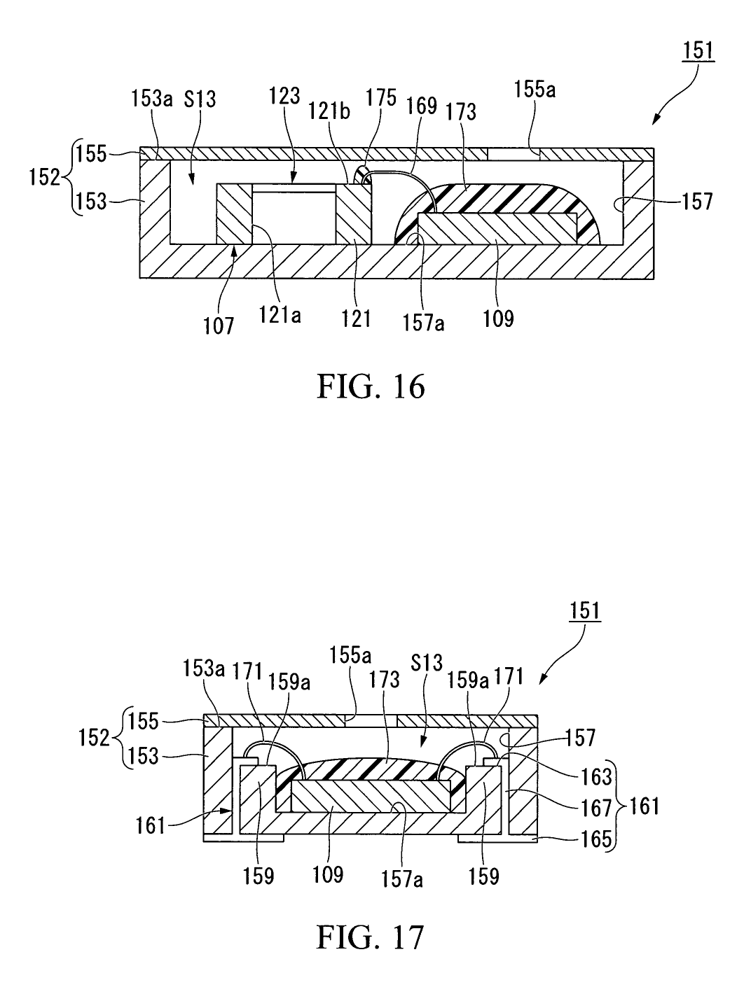

Next, a semiconductor device 151 according to a third variation of the second embodiment will be described with reference to FIGS. 15 to 17. The semiconductor device 151 is designed such that the semiconductor sensor chip 107 and the control circuit chip 109 are arranged inside of a housing 152 constituted of a multilayered wiring substrate 153 and a top portion (or a cover member) 155.

In the semiconductor device 151, i.e., in the multilayered wiring substrate 153 of the housing 152, a recess 157 is recessed downwardly from a surface 153a of the multilayered wiring substrate 153. The semiconductor sensor chip 107 and the control circuit chip 109 are mounted on a bottom (serving as a mounting surface) 157a of the recess 157. Step portions 159, which project upwardly from the bottom 157a of the recess 157, are formed and elongated on both sides of the alignment of the semiconductor sensor chip 107 and the control circuit chip 109.

A plurality of external connection wires 161 are formed on the multilayered wiring substrate 153 so as to electrically connect the semiconductor sensor chip 107 and the control circuit chip 109 to a circuit board (not shown) for mounting the semiconductor device 151.

As shown in FIG. 17, each of the external connection wires 161 is constituted of an internal terminal 163, which is exposed on an upper surface 159a of the step portion 159 and is electrically connected to the control circuit chip 109, an external terminal 165, which is exposed on a backside 153c of the multilayered wiring substrate 153 and is used to establish an electrical connection with the circuit board, and a conductor 167, which is formed inside of the multilayered wiring substrate 153 so as to establish an electrical connection between the internal terminal 163 and the external terminal 165.

As shown in FIG. 15, the control circuit chip 109 is electrically connected to the electrode pads 125 of the semiconductor sensor chip 107 via first bonding wires 169 and is electrically connected to the internal terminals 163 of the multilayered wiring substrate 153 via second bonding wires 171.

In the semiconductor device 151, the top portion 155 having a sound hole 155a is formed in a plate-like shape and is composed of a conductive material. When the top portion 155 is fixed onto the surface 153a of the multilayered wiring substrate 153, the top portion 155 covers the opening of the recess 157 so as to form a cavity S13 embracing the semiconductor sensor chip 107 and the control circuit chip 109 together with the multilayered wiring substrate 153. The cavity S13 communicates with the exterior via the sound hole 155a.

When the top portion 155 is attached onto the surface 153a of the multilayered wiring substrate 153, it is electrically connected to connection pads (not shown) formed on the surface 153a of the multilayered wiring substrate 153. The connection pads are connected to ground external terminals (not shown), which are exposed on the backside 153c of the multilayered wiring substrate 153, via conductors (not shown) formed on the interior or side surface of the multilayered wiring substrate 153.

The control circuit chip 109 and the joining portions, at which the control circuit chip 109 joins first bonding wires 169, are sealed with a resin sealing portion 173 that is formed above the bottom 157a of the recess 157 in the multilayered wiring substrate 153. The height of the resin sealing portion 173 is lower than the height of the upper surface 121b of the semiconductor sensor chip 107, so that the sound detector 123 is exposed externally of the resin sealing portion 173 from the upper surface 121b of the semiconductor sensor chip 107.

A resin potting portion 175, which is composed of the same material of the resin sealing portion 173, is formed on the upper surface 121b of the semiconductor sensor chip 107 so as to seal the joining portions at which the electrode pads 125 of the semiconductor sensor chip 107 join the first bonding wires 169.

In the manufacturing of the semiconductor device 151, the multilayered wiring substrate 153 is prepared in advance.

The multilayered wiring substrate 153 can be produced individually. Alternatively, a plurality of multilayered wiring substrates 153 linked together are produced collectively, and then they are divided into individual pieces.

Next, the semiconductor sensor chip 107 and the control circuit chip 109 are adhered and fixed onto the bottom 157a of the recess 157 in the multilayered wiring substrate 153 via a die-bonding material in a mounting step. As the die-bonding material, it is possible to use the aforementioned insulating adhesive, die-attach film, and the like. Of course, it is possible to use the conductive adhesive.

Thereafter, wire bonding is performed so as to arrange the first bonding wires 169 between the semiconductor sensor chip 107 and the control circuit chip 109 and to arrange the second bonding wires 171 between the control circuit chip 109 and the internal terminals 163, thus electrically connecting the semiconductor sensor chip 107 and the external connection wires 161 via the control circuit chip 109 in a wiring step.

In a sealing step, the resin sealing portion 173 is formed to seal the surface 103a of the substrate 103, the control circuit chip 109, and the joining portions between the control circuit chip 109 and the distal ends of the first bonding wires 169, and the resin potting portion 175 is formed to seal the joining portions between the electrode pads 125 of the semiconductor sensor chip 107 and the distal ends of the first bonding wires 169. In the sealing step, the joining portions between the control circuit chip 109 and the distal ends of the second bonding wires 171 are sealed with the resin sealing portion 173 as well.

Lastly, a cover installation step is performed so as to fix the top portion 155 onto the surface 153a of the multilayered wiring substrate 153 by use of the conductive adhesive, for example. Thus, it is possible to complete the manufacturing of the semiconductor device 151.

The semiconductor device 151 and its manufacturing method offer effects similar to the foregoing effects demonstrated by the semiconductor device 101 according to the second embodiment and its variations.

In the semiconductor device 151, the sound hole 155a is formed in the top portion 155; but this is not a restriction. Instead of the sound hole 155a, it is possible to form another sound hold allowing the cavity S3 to communicate with the exterior in the multilayered wiring substrate 153.

The resin potting portion 175 is not necessarily formed to seal only the joining portions between the electrode pads 125 and the distal ends of the first bonding wires 169. In addition to the aforementioned joining portions, the resin potting portion 175 can be formed to seal the other joining portions between the external connection wires 161 (exposed on the upper surface 159a of the step portion 159) and the distal ends of the second bonding wires 171.

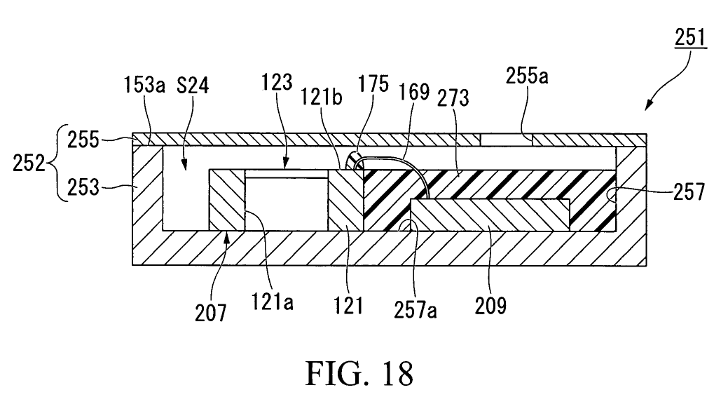

A semiconductor device 251 according to a fourth variation of the second embodiment will be described with reference to FIG. 18. Herein, a resin sealing portion 273 sealing a control circuit chip 209 is formed inside of a housing 252 so as to cover the surface of the surrounding area of a semiconductor sensor chip 207. In the semiconductor device 251, the housing 252 is constituted of a multilayered wiring substrate 253 and a top portion (or a cover member) 255. The housing 252 has a cavity S24 defined by the multilayered wiring substrate 253 and the top portion 255. The multilayered wiring substrate 253 forms a recess 257 having a mounting surface (or a bottom) 257a, on which the semiconductor sensor chip 207 and the control circuit chip 209 are mounted. The overall constitution of the semiconductor device 251 is basically identical to the aforementioned constitution shown in FIGS. 15, 16, and 17 except for the resin sealing portion 273. The resin sealing portion 273 is shaped to cover the control circuit chip 209 and to cover the surface of the surrounding area of the semiconductor sensor chip 207. That is, the housing 252 is partially occupied by the resin sealing portion 273 in such a way that the height of the resin sealing portion 273 is substantially identical to the height of the semiconductor sensor chip 207 above the mounting surface 257a.

The semiconductor device 251 offers the outstanding effect for preventing the joining portions between the control circuit chip 209 and the electrode pads and bonding wires from being corroded.

When the semiconductor device 251 serves as a microphone package so that the semiconductor sensor chip 207 serves as a microphone chip, it is preferable that the volume of the resin sealing portion 273 be larger than a half of a prescribed volume, which is calculated by subtracting the volume of the semiconductor sensor chip 207 and the volume of the control circuit chip 209 from the volume of a cavity S24 of the housing 252, and be smaller than the volume of the cavity S24. By appropriately controlling the volume of the resin sealing portion 273 as described above, the semiconductor device 251 can offer the foregoing effect realized by the first embodiment; that is, it is possible to increase the resonance frequency of the housing 252 to be higher than the audio frequency range. Therefore, even when a sound hole 255a formed in the top portion 255 is reduced in size, it is possible for the microphone package to improve the quality of sound detection.

Next, an additional description will be given with respect to the semiconductor device 101 of the second embodiment shown in FIG. 2. That is, when the semiconductor device 101 servers as a silicon microphone package so that the semiconductor sensor chip 107 serves as a microphone chip, it is preferable that the volume of the resin sealing portion 111 be larger than a half of a prescribed volume, which is calculated by subtracting the volume of the semiconductor sensor chip 107 and the volume of the control circuit chip 109 from the volume of a cavity S10, which is defined by the substrate 103, the resin mold portion 117, the dam 113, and the top portion 115, and be smaller that the volume of the cavity S10. In other words, it is preferable that the volume of the cavity S12 be smaller than a half of the prescribed volume, which is calculated by subtracting the volume of the semiconductor sensor chip 107 and the volume of the control circuit chip 109 from the volume of the cavity S10.

By appropriately controlling the volume of the resin sealing portion 111 as described above, the semiconductor device 101 can offer the foregoing effect realized by the first embodiment; that is, it is possible to increase the resonance frequency of the housing to be higher than the audio frequency range. Therefore, even when the sound hole 115a is reduced in size, it is possible for the microphone package to improve the quality of sound detection.

Lastly, the present invention is not necessarily limited to the first and second embodiments as well as their variations; hence, it is possible to realize a variety of variations within the scope of the invention as defined in the appended claims.

What is claimed is:

1. A microphone package comprising:
a housing having a cavity and a sound hole allowing the cavity to communicate with an exterior thereof, wherein a microphone chip is mounted on a mounting surface inside of the cavity and wherein the sound hole is opened on an interior surface of the housing positioned opposite to the mounting surface; and
a resin sealing portion that is formed inside of the cavity so as to seal a surrounding area of the microphone chip and the mounting surface.

2. A microphone package according to claim 1, wherein a volume of the resin sealing portion is smaller than a volume of the cavity but is larger than a half of a prescribed volume, which is calculated by subtracting a volume of the microphone chip from the volume of the cavity.

3. A microphone package according to claim 1, wherein the resin sealing portion is composed of a silicon resin, and wherein the microphone chip includes a diaphragm, which covers an inner hole of a support and which is arranged opposite to the mounting surface via the support.

4. A microphone package according to claim 2, wherein the resin sealing portion is composed of a silicon resin, and wherein the microphone chip includes a diaphragm, which covers an inner hole of a support and which is arranged opposite to the mounting surface via the support.

5. A microphone package according to claim 1 further comprising:
a control circuit chip that is mounted on the mounting surface inside of the cavity so as to drive and control the microphone chip;
a plurality of bonding wires for electrically connecting the microphone chip and the control circuit chip together; and
a resin sealing portion for entirely sealing the control circuit chip so as to embrace first joining portions between the control circuit chip and first ends of the bonding wires,
wherein the microphone chip has a sound detector that detects pressure variations by way of vibration thereof and that is exposed onto an upper surface of the microphone chip,
wherein a plurality of electrode pads are formed in a surrounding area of the sound detector so as to join second ends of the bonding wires, and
wherein second joining portions between the electrode pads and the second ends of the bonding wires are sealed with a resin potting portion that is formed using a same resin material of the resin sealing portion.

6. A microphone package according to claim 5, wherein a recess is formed between the sound detector and the electrode pads and is recessed from the upper surface of the semiconductor sensor chip to a prescribed position, which is lower than an upper end of the sound detector.

7. A microphone package according to claim 5, wherein a dam is formed between the electrode pads and the sound detector so as to project upwardly from the upper surface of the microphone chip.

8. A microphone package according to claim 7, wherein the dam is formed to surround the electrode pads.

9. A microphone package according to claim 5, wherein the housing is constituted of a substrate for mounting the microphone chip on a mounting surface positioned opposite to the sound detector, the resin sealing portion for sealing a surrounding area of the microphone chip and the surface of the substrate, a dam that projects upwardly from the microphone chip so as to surround a periphery of the sound detector, and a top portion, which has the sound hole running through in a thickness direction and which is fixed to a distal end of the dam so as to cover an upper side of the semiconductor sensor chip, and wherein the cavity is formed by way of the resin sealing portion, the dam, and the top portion.

10. A manufacturing method for a semiconductor device, in which a semiconductor sensor chip having a sound detector for detecting pressure variations by way of vibration and a control circuit chip for driving and controlling the semiconductor sensor chip are arranged inside of a housing having a cavity and a sound hole allowing the cavity to communicate with an exterior, said manufacturing method comprising:
a mounting step for mounting the semiconductor sensor chip and the control circuit chip onto a surface of a substrate;
a wiring step for electrically connecting the control circuit chip to a plurality of electrode pads, which are formed on an upper surface of the semiconductor sensor chip for exposing the sound detector, via a plurality of bonding wires;
a sealing step for forming a resin sealing portion for entirely sealing the control circuit chip so as to embrace first joining portions between the control circuit chip and first ends of the bonding wires, and a resin potting portion for sealing second joining portions between the electrode pads and second ends of the bonding wires; and
a cover installation step for arranging a top portion so as to cover an upper side of the semiconductor sensor chip and an upper side of the control circuit chip above the mounting surface of the substrate, thus forming the housing having the cavity together with the substrate,
wherein, in the sealing step, both of the resin sealing portion and the resin potting portion are formed using a same resin material.
